(19) United States
(12) Patent Application Publication
(10) Pub. No.: US 2025/0085698 A1
(43) Pub. Date: Mar. 13, 2025

(54) OPTIMISATION-BASED SCHEDULING METHOD AND SYSTEM FOR A PLURALITY OF MANUFACTURING MACHINES

(71) Applicant: FLEXCITON LIMITED, London (GB)

(72) Inventors: Dionysios XENOS, London (GB); Ioannis KONSTANTELOS, London (GB); Ruaridh WILLIAMSON, London (GB)

(21) Appl. No.: 18/720,285

(22) PCT Filed: Dec. 9, 2022
(86) PCT No.: PCT/GB2022/053168

§ 371 Date: Jun. 14, 2024

(30) Foreign Application Priority Data
Dec. 14, 2021 (GB) 2118120.1

(51) Int. Cl. G05B 19/418; G06F 30/27

(52) U.S. Cl. CPC G05B 19/41865; G05B 19/41885; G06F 30/27; G05B 2219/45031

(57) ABSTRACT

The present invention relates to the generation of scheduling data for machinery. More particularly, the present invention relates to modelling machinery capabilities and states, planned inputs, outputs and constraints in order to generate priorities for a schedule for manufacturing machinery. Aspects and/or embodiments seek to provide a method and system of generating scheduling data that can be used in complex manufacturing settings such as semiconductor wafer fabrication plants.

### FIELD

The present invention relates to the generation of scheduling data for machinery. More particularly, the present invention relates to modelling machinery capabilities and states, planned inputs, outputs and constraints in order to generate priorities and/or other scheduling data for a schedule for manufacturing machinery.

### BACKGROUND

In complex manufacturing settings, such as for example semiconductor wafer fabrication plants, a plurality of machinery is used in specific orders to output a variety of different semiconductor products from the fabrication plants.

Currently, each of the machines (sometimes termed tools or toolsets) is provided with a rules-based local scheduler that schedules the tasks received by that machine to be performed. These tasks are generated and distributed centrally from a central Manufacturing Execution System (or “MES”) to the machines, typically via dispatching software.

The MES receives the planned outputs (e.g. the quantities of each type of output product to be produced in the fabrication plant) from the operators of the fabrication plant and/or the dispatching software pulls the scheduling output (for example, the respective priorities of tasks) directly, and uses pre-determined workflows for each type of output product to send tasks to each relevant machine in the fabrication plant, for example to operators via a user interface or directly to manufacturing tools/machines for automatic execution.

Each machine receives these tasks as they are generated, along with various metadata about each task (for example the urgency of the task and/or a priority rating) and, using a set of pre-determined rules, orders the current list of tasks to be performed using these pre-determined rules.

Automated material handling systems (i.e. robots) and/or humans are required to move partially finished products between machines, for complex products that require a sequence of processes to be performed by specific machines in a specific order. Some of these complex products need to be completed within a certain period of time from beginning the process of their manufacture at the first machine until the completion of the process of their manufacture at the final machine.

However, the pre-determined rules can often incorrectly prioritise the tasks at each machine, resulting in partially manufactured complex items not being completed within the required period of time and becoming damaged (for example by oxidising having been left exposed to air for too long).

Due to the complexity of manufacture of these complex products, and the parallel production of multiple different complex products at the same time as relatively simple products, and the desire of the fabrication plant operators to utilise as many machines as fully as possible to optimise efficiency, an improved approach is required.

### SUMMARY OF INVENTION

Aspects and/or embodiments seek to provide a method and system of generating scheduling data that can be used in complex manufacturing settings such as semiconductor wafer fabrication plants.

According to a first aspect, there is provided a computer-implemented method of generating manufacturing scheduling data, comprising: receiving input data, the input data comprising: at least one product to be manufactured; at least one sequence of steps associated with each of the at least one product to be manufactured; and at least one constraint associated with each of the at least one sequence of steps; performing a plurality of different simulations of manufacturing the at least one product to be manufactured; wherein each of the plurality of different simulations uses different simulation parameters; and wherein each simulation determines a probability of breach of at least one of the at least one constraints; determining a manufacturing schedule of the at least one product to be manufactured using the determined probability of breach of at least one of the at least one constraints; determining a priority of each step in the at least one sequence of steps based on the determined manufacturing schedule; generating manufacturing scheduling data, wherein the manufacturing scheduling data comprises one or more of the at least one sequence of steps associated with each of the at least one product to be manufactured and the determined priorities of the one or more of the at least one sequence of steps associated with each of the at least one product to be manufactured; outputting the generated manufacturing scheduling data.

By conducting simulations for each of the manufacturing processes, the various constraints associated to each sequence of manufacturing steps can be assessed to determine the possibility or probability of a real-world breach in the form of a manufacturing or process defect. Based on the results of the simulations, manufacturing scheduling data can be generated which can be used provide an optimal ordered set of tasks per machine which ensure that predicted violations of constraints are minimised. Additionally, the generated manufacturing scheduling data can in some embodiments be provided directly as instructions to a plurality of machines, factories, servers and/or manufacturing plants to produce at least some of the plurality of products to be manufactured. In other embodiments, to allow schedulers that prepare schedules for specific groups of machines, single types of machine, or machines used in sequence, scheduling data is provided to these schedulers in order for these to generate manufacturing schedules for their respective machines.

Optionally, determining a priority of each step based on the determined manufacturing schedule further comprises determining the priority of each step based on the determined probability of breach of at least one of the at least one constraint. In this way any likely breaches of constraints are considered when determining priorities, for example, allocating a lower priority to tasks likely to breach a constraint to prevent or reduce the likelihood of them being scheduled. Accordingly, the resulting generated schedules can reduce the probability of scrap/long cycle times and can keep the probability of scrap/breaching constraints within user-defined acceptable values.

Optionally, the at least one product to be manufactured comprises any or any combination of: a semiconductor wafer product. This enables generation of optimal and efficiency manufacturing scheduling data for the manufacture of complex products across a wide variety of industries. The term “fab” will be understood to refer to a factory in which semiconductor products are manufactured, for example a wafer fabrication plant.

Optionally, the at least one sequence of steps associated with each of the at least one products to be manufactured comprises any or any combination of: steps to take in parallel; steps to take in sequence. This can enable scheduling for products that require a specific sequence of steps to be performed to output a finished product, or in settings where multiple different products are manufactured in parallel using at least some common facilities/machines/tools/resources.

Optionally, the input data further comprises at least one buffer item to be released; wherein the at least one product to be manufactured requires one or more of the at least one buffer items during its manufacture. The buffer can store work in progress (WIP) items, flows, tasks or sequences with no quality or physical constraints. This can provide or assist with an efficient management system for the volume of WIP in the factory, each manufacturing sequence, or one or more machinery performing one or more operations.

Optionally, determining a manufacturing schedule further comprises determining when to release one or more of the at least one buffer items to be released. This can ensure a substantially controlled WIP flow which avoids bottlenecks at downstream machines (e.g. machines required for future steps/tasks in order to complete manufacture of a lot/product).

Optionally, determining a priority further comprises determining a priority of when to release one or more of the at least one buffer items to be released. This can enable the relative urgency of the release of the one or more of the at least one buffer items to be determined.

Optionally, at least one constraint comprises any or any combination of: a time link constraint; a resource constraint; a product completion target associated with one or more of the at least one products to be manufactured. This results in an output schedule which can substantially optimise the use of resources measured against a set of constraints/objectives.

Optionally, the input data further comprises a criticality value for at least one of the at least one constraints, wherein the criticality value optionally further comprises at least one priority value. Using criticality values can indicate the relative urgency or importance that each of the constraints are met and/or of one or more of the products to be manufactured.

Optionally, the input data further comprises availability data of a plurality of manufacturing machines, wherein the at least one product to be manufactured is manufactured using the one or more of the manufacturing machines. Availability data can aid in both the determination of a predicted outcome of at least some of the tasks to be performed and can aid in preparing a substantially optimal order of tasks per machine.

Optionally, performing the plurality of simulations comprises performing simulations using any or any combination of: Monte-Carlo simulations; mathematical optimisation; heuristic search; decomposition methods; statistical distributions of the simulation parameters optionally wherein the statistical distributions are used in Monte-Carlo simulations. Each simulation can determine a predicted outcome of at least some of the tasks to be performed. Based on the results of the simulations, an output schedule which allows for more optimal use of resources can be generated.

Optionally, performing the plurality of simulations comprises preparing a ranking of the at least one product to be manufactured and/or each step in the at least one sequence of steps associated with each of the at least one product to be manufactured based on the one or more criticality values. By assigning higher priority to steps and/or products with an earlier due date, more timelink constraints, and a higher number of steps to be scheduled, embodiments can ensure that substantially all timelink violations are minimised.

Optionally, performing the simulations comprises performing simulations of manufacturing only the at least one product to be manufactured within a predetermined time frame. This provides a predicted outcome of manufacturing the at least one product, based on the availability of the plurality of machines and any pre-determined constraints, along with a probability of breaching any constraints. The plurality of machines can then be instructed to perform the plurality of tasks using the generated scheduling data to produce at least some of the at least one product to be manufactured.

Optionally, determining the manufacturing schedule further comprises determining any further constraints associated with one or more of the at least one sequence of steps. This can enable determination, measured against the set of constraints/options, of whether any simulated options for the schedule result in a substantially better outcome. Scheduling the at least one sequence of steps to minimise constraint violations can have a significant impact on yield management by reducing the likelihood of rework, scrap or longer cycle time.

Optionally, determining the manufacturing schedule further comprises determining any or any combination of: an earliest and/or latest release time associated with one or more of the at least one product to be manufactured and/or one or more of the at least one sequence of steps associated with each of the at least one product to be manufactured. This can enable higher priority/priorities to be allocated to products and/or sequences of steps with earliest due date.

Optionally, determining the manufacturing schedule comprises using any or any combination of: mixed integer linear programming; a mixed integer linear programming model; relaxed mixed integer linear programming; a relaxed mixed integer programming model; a flow control model; a real-time dispatch heuristic. This can enable optimisation approaches to construct the schedule within constraints. A two-stage solution strategy combining mixed integer linear programming (MILP) models and heuristics can provide substantially significant improvements in scheduling.

Optionally, determining the manufacturing schedule further comprises using the at least one constraint. This can enable the outcome of one or more simulations to be obtained, each simulation determining a predicted outcome of at least some of the tasks to be performed. The probability of breaching the at least one constraint can also be obtained.

Optionally, determining the manufacturing schedule is performed only for the at least one product to be manufactured where the determined probability of breach of at least one of the at least one constraints is below a predetermined threshold. This can enable feedback to be given to aid both lot selection by the lot selection module 220, which determines lot releases (as described in the specific description below), and to the scheduling module 225 which implements the multi-machine/fab-wide solution, to reduce the risk of time link violations. A new multi-machine/fab-wide scheduling run/iteration can be triggered should the time link violations exceed the expected and/or accepted risk/tolerance for violations.

Optionally, determining a priority of each step in the at least one sequence of steps comprises using a model of the one or more manufacturing machines to be used to manufacture the at least one product to be manufactured. This can result in an output schedule which allows for more optimal use of available resources in a manufacturing facility having multiple (identical and/or different) machines. Additionally, this accounts for the fact that each machine, despite being part of a group of machines of the same type, may be programmed with different recipes and vary in speed to complete certain tasks.

Optionally, the model of the one or more manufacturing machines is generated from historical data from the one or more manufacturing machines and/or current data from the one or more manufacturing machines. This can enable the high-level optimisation model to be generated and updated based on historical data and/or current data for the specific manufacturing facility/machines for which it maintains models.

Optionally, the manufacturing scheduling data further comprises the determined further constraints. This can enable the generation of manufacturing scheduling data based on the results of simulations subject to constraints, along with a probability of breaching the constraints, in order to determine an optimal output schedule which minimises breaches of the constraints.

Optionally, the output generated manufacturing scheduling data is communicated to any or any combination of: one or more manufacturing execution system; the one or more manufacturing machines; one or more schedulers. This can allow operators to execute the instructions in the schedule provided through the signal being sent either to the Manufacturing Execution System(s) (MES), the dispatching software/system, or directly to the machine(s), or to schedulers specific to a machine, a group of machines, or a sequence of machines.

According to another aspect, there is provided a method of generating scheduling data for manufacturing comprising: receiving input data, the input data comprising a plurality of products to be manufactured and a plurality of tasks to be performed by each of a plurality of machines and wherein each of the plurality of tasks to be performed has a priority value associated therewith; performing one or more simulations, each simulation determine a predicted outcome of at least some of the tasks to be performed, based on the availability of the plurality of machines and any pre-determined constraints, along with a probability of breaching any constraints; determining a substantially optimal predicted outcome of the one or more simulations using pre-determined criteria; generating scheduling data comprising an ordered set of tasks per machine based on the simulation used to determine the substantially optimal predicted outcome; and instructing the plurality of machines to perform the plurality of tasks using the generated scheduling data to produce at least some of the plurality of products to be manufactured.

By generating a schedule having performed one or more simulations of the outcomes to determine whether any options for the schedule result in a substantially better outcome (for example measured against a set of constraints/objectives), the output schedule can allow for more optimal use of resources in a manufacturing facility or other facility (such as a wafer fabrication plant) having multiple (identical and/or different) machines and also multiple output products that can be produced. In other embodiments, performing simulations allows for identification of breaches of any constraints, such as time link constraints, that would result in lots failing to meet quality control requirements and this allows for removal or deprioritising of lots when preparing scheduling for manufacturing tools/machines.

In embodiments, at least some of the plurality of tasks are performed in order to produce at least some of the plurality of products.

Optionally, the method further comprises a step of pre-processing the plurality of tasks to be performed to select at least some of the plurality of tasks as a subset of tasks to be used by the one or more simulations to determine a predicted outcome of the subset of tasks to be performed.

In some embodiments, the lots of tasks contain complex inter-related tasks that need to be performed in specific sequences and where one or more steps in the sequence need to be performed within specific time constraints (also known as time links or Qtime constraints or timelag constraints or close couples), and by pre-processing these lots it can assist with optimising a schedule to allow the lots to be manufactured without violating the time constraints.

Optionally, manufacturing comprises any or any combination of: wafer fabrication; semiconductor wafer fabrication; semiconductor manufacturing; computer chip manufacturing; automotive manufacturing; computer manufacturing; computer hard drive manufacturing; computer memory manufacturing;

The method of aspects and/or embodiments can be used across a wide variety of industries in which complex products are manufactured, or products that require a specific sequence of steps to be performed to output the finished product, or in settings where multiple different products are manufactured in parallel using at least some common facilities/machines/tools/resources.

Optionally, the input data further comprises any or any combination of: a state of the plurality of machines; an initial state of one or more resources; a state of a fabrication facility: one or more locations of any relevant products; a current task of one or more of the machines; an idle state of one or more of the machines; a maintenance state of one or more of the machines; a demand of one or more of the products; a priority of one or more products; specific due dates of one or more products.

Optionally, receiving richer data on the current state of the resources available can assist in generating a schedule that substantially optimises use of resources and outputs the prioritised and/or target manufactured end products.

Optionally, the method further comprises any or any combination of pre-processing steps including any or any combination of: validating the input data quality; reconstructing the input data; combining the input data to generate parameter values.

Optionally, some steps to validate and/or optimise the input data can be performed to improve the input data quality and thereby substantially improve the output scheduling.

Optionally, the plurality of products to be manufactured comprises any or any combination of: computer chips; computer memory; computer storage; semiconductors; wafers; hard drives; random access memory; solid state memory; storage chips.

The method of aspects and/or embodiments can be used across a wide variety of industries in which complex products are manufactured, or products that require a specific sequence of steps to be performed to output the finished product, or in settings where multiple different products are manufactured in parallel using at least some common facilities/machines/tools/resources.

Optionally, the plurality of machines comprises any or any combination of: metrology equipment; furnace equipment; cleaning equipment; photolithography equipment.

The method of aspects and/or embodiments can be used across a wide variety of industries in which complex products are manufactured, or products that require a specific sequence of steps to be performed to output the finished product, or in settings where multiple different products are manufactured in parallel using at least some common facilities/machines/tools/resources.

Optionally, the priority value of each of the plurality of tasks indicates any or any combination of: an urgency value; an importance value; a relative urgency value; a relative importance value.

Optionally, receiving richer data on the current state of the resources available can assist in generating a schedule that substantially optimises use of resources and outputs the prioritised and/or target manufactured end products.

Optionally, performing one or more simulations comprises using one or more predictive models.

Optionally, the one or more predictive models comprise any or any combination of: a mixed integer linear programming model; heuristics; complex flexible job-shop-scheduling problem with time link constraints model; integer programming model; metaheuristics; mixed integer programming model; genetic algorithm; simulated annealing; greedy randomised adaptive search procedure; constraint programming model; Monte Carlo methods; multivariate predictive models; relaxed mixed integer linear programming model.

A variety of models/techniques can be used to provide a substantially optimal schedule for the manufacturing facility.

Optionally, the method is repeated in iterations over a period of time.

The method is be repeated at time periods in at least some embodiments, which can allow the scheduling method to consider only the tasks due to be performed within a limited time period thus allowing the computation to be performed without over-complicating the scheduling to include tasks that do not need to be scheduled.

Optionally, performing one or more simulations comprises predicting one or more violations that would result in manufacturing defects and wherein determining the substantially optimal predicted outcome comprises substantially minimising predicted violations.

Optionally, the input data comprises a predetermining tolerance level of violations and wherein substantially minimising predicted violations comprises determining that the substantially optimal predicted outcome results in fewer violations than the predetermining tolerance level of violations.

By performing one of more simulations, an assessment of one or more different options for scheduling can be tested and the one substantially optimal schedule chosen based on predetermined criteria. The criteria can include a predetermined tolerance level for violations, for example of time link constraints and/or other constraints, and this can allow the output schedule to be one that minimises violations.

Optionally, the method further comprises a step of determining a level of robustness of the substantially optimal predicted outcome; and determining whether the level of robustness exceeds a predetermined tolerance level of robustness.

A determination can be made of the robustness of the schedule that is output from the optimisation method.

Optionally, the generated scheduling data comprises only any or any combination of: task priority data for one or more tasks; earliest task start time(s); latest task start time(s).

The scheduling data in some embodiments can include only priority data and/or earliest start times and/or latest start times. This data can then be used by schedulers specific to single machines, groups of the same type of machine, or schedulers that operate across sequences of machines to create schedules for their respective machines based on the output of the fab-wide scheduler.

According to a further aspect, there is provided a system comprising a plurality of machines and operable to perform the method of either other aspect.

According to another aspect, there is provided a method of generating scheduling data for manufacturing comprising: receiving input data, the input data comprising a plurality of products to be manufactured and a plurality of tasks to be performed by each of a plurality of machines and wherein each of the plurality of tasks to be performed has a priority value associated therewith; using a predictive model of the plurality of machines to determine a substantially optimal order of tasks per machine, based on the availability of the plurality of machines and any pre-determined constraints, along with a probability of breaching any constraints, is output; and generating scheduling data comprising an ordered set of tasks per machine wherein scheduling data is operable to be used by the plurality of machines to manufacture at least some of the plurality of products to be manufactured.

### BRIEF DESCRIPTION OF DRAWINGS

Embodiments will now be described, by way of example only and with reference to the accompanying drawings having like-reference numerals, in which:

FIG. 1 shows an example of a computer system, such as a distributed network or a cloud server, comprising a factory computer system according to an embodiment, in communication with a factory containing groups of manufacturing machines/tools;

FIG. 2 shows an example of a computer system, such as a distributed network or a cloud server, comprising a local computer system according to an embodiment, in communication with a factory containing groups of manufacturing machines/tools;

FIG. 3 shows an example of machines and products within the factory or a manufacturing plant;

FIG. 4 shows an example of movement of a product between different machines in the factory;

FIG. 5 shows time constraints for a single lot according to an embodiment, where for example a single lot may represent a single type of product to be manufactured and where for example each step in the manufacture is performed by a different manufacturing tool or machine, and where there is a time limit (also known as a time link) between the performance of each step that should not be breached in order to meet a desired quality requirement for the product to be manufactured;

FIG. 6 shows multi-machine (also known as fab-wide) and local scheduling in a wafer fabrication facility according to an embodiment where a fab-wide scheduler (also known as a multi-machine scheduler) provides scheduling data to different types of toolset schedulers including multi-step schedulers and/or single toolset schedulers;

FIG. 7 shows a robustness assessment approach according to an embodiment being used alongside the fab-wide scheduler;

FIG. 8 shows the simulation of a lot scheduling approach according to an embodiment;

FIG. 9 shows more detail of the simulation of the lot scheduling approach of FIG. 8;

FIG. 10 shows more detail of the simulation of the lot scheduling approach of FIG. 8 where scheduling violations (i.e. breaches of constraints) are identified;

FIG. 11 shows more detail of the simulation of the lot scheduling approach of FIG. 8 where total predicted violations per lot are compared to pre-determined acceptable violation level thresholds;

FIG. 12 shows more detail of the simulation of the lot scheduling approach of FIG. 8 where, using the simulation output, lots are removed from scheduling;

FIG. 13 shows a method of generating a schedule for a group of machines, according to an embodiment;

FIG. 14 shows a multi-step scheduling approach according to an embodiment; and

FIG. 15 shows both a multi-step and a single-step toolset scheduler approach using the scheduling data output by the fab-wide scheduler according to an embodiment.

### SPECIFIC DESCRIPTION

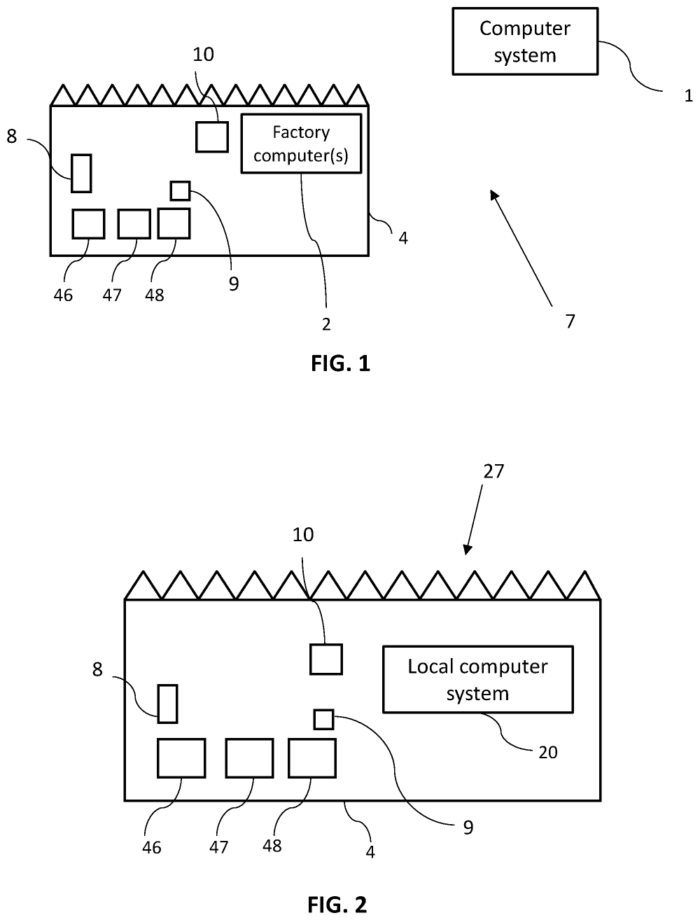

Referring to FIGS. 1 to 15, aspects and/or embodiments of the invention will now be described with reference to each Figure in turn.

FIG. 1 shows an embodiment of a system 7 in accordance with the present invention. The system 7 comprises a computer system 1 for generating scheduling data for a group of machines in the factory 4. The computer system 1 comprises one or more computers.

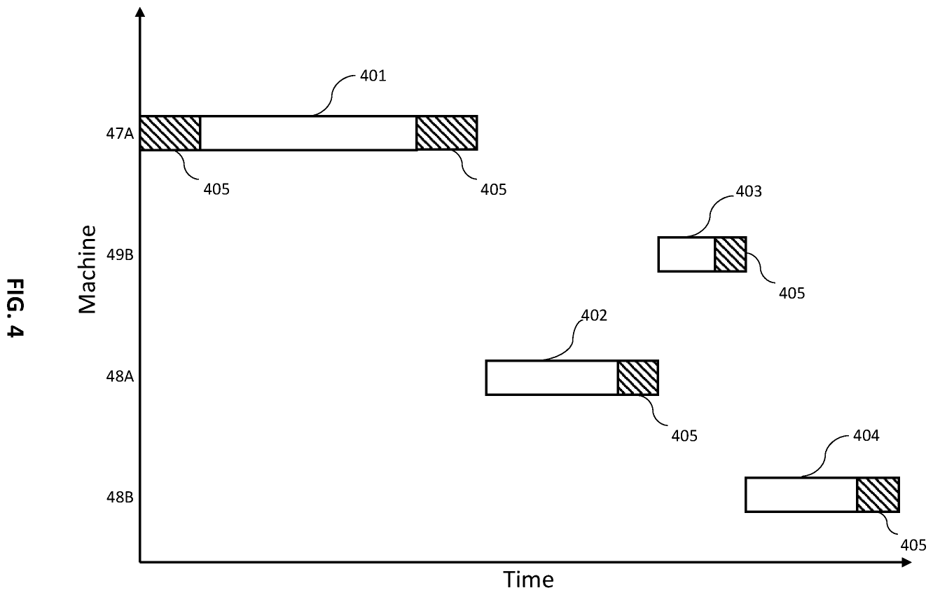

The factory 4 comprises groups of machines 46, 47, 48 for manufacturing products such as semiconductor wafers. The groups of machines each contain one or more machines, an example of which is described below in more detail in relation to FIG. 3.

The computer system 1 is configured to generate scheduling data for the group of machines according to the method described herein. Having generated the scheduling data for the group of machines, the computer system 1 can then provide scheduling data to the group of machines in the factory 4 via a communication means. The scheduling data can include a manufacturing schedule or manufacturing tasks, and this schedule or these tasks can further include priority information and/or earliest manufacturing start and/or finish times.

The communication means may comprise one or more user interfaces 8 in the factory. The user interface(s) 8 displays the schedule for the groups of machines 46, 47, 48 so that people working in the factory can operate the machines in accordance with the schedule. Alternatively or additionally, the communication means comprises means to transmit control signals 9, wherein the control signals automatically operate the machines in the groups of machines in accordance with the schedule for the group of machines and/or wherein the control signals automatically operate processes in the factory to enable the machines to operate in accordance with the schedule for the group of machines. Automatically operating processes in the factory may, for example, involve operating an automated manual handling system (or “AMHS”) to move products or resources in the factory, for example so that these products or resources are present at the machines at the times required by the schedule.

The means to transmit control signals 9 may include, for example, a network connection from the computer system 1 to the groups of machines 46, 47, 48 and/or to robots in the factory or to the AMHS, which moves the products and additional resources around the factory. Alternatively, the means to transmit control signals 9 may include a factory computer(s) 2 which is in communication with the first computer system 1 and the machines and/or robots in the factory or the AMHS, such as via a wired or a wireless connection.

The computer system 1 may provide the schedule or scheduling data to the user interfaces 8 directly, for example via a network, or indirectly, such as via a computer or computers 2 located in the factory 4. The computer system 1 may be connected to the factory computer(s) 2 via a network. Similarly, the computer system 1 may provide the schedule or scheduling data to the means to transmit control signals 9 directly or indirectly via the factory computers 2.

The system 7 may comprise a means for collecting data from the factory 10, and a means for sending the collected data to the computer system 1. The means for collecting data from the factory 10 and the means for sending the collected data to the computer system may be part of a Manufacturing Execution System (MES) or any other software system used to handle manufacturing data e.g. dispatching software. In some embodiments, the factory computer(s) 2 host or incorporate the MES but in other embodiments a separate means is provided to host or provide the MES.

The means for collecting data from the factory 10 may include, for example RFID or bar code tagging of products and additional resources in the factory, or sensors in the factory to gather data about the products, machines or additional resources, or data collection from one or more of the group of machines.

The means for sending the collected data to the computer system 1 may comprise one or more computers in communication with the means for collecting data from the factory 10, such as via a wired or wireless connection. The means for sending the collected data to the computer system 11 may be in communication with the computer system 1, for example via a network.

In some embodiments, the means for sending the collected data to the computer system may send the data to the computer system 1 multiple times at a first frequency, and also at a second frequency which is higher than the second frequency. The first frequency may be, for example, 5 minutes, and the second frequency may be, for example, 30 seconds or less. The data sent at the second frequency may be a subset of the data sent at the first frequency. Alternatively, the means for sending the collected data to the computer system 1 may send the data only at a single frequency.

The data which is collected and sent from the factory to the computer system is updated each time that it is sent to convey the most up to date data from the factory. The computer system 1 uses the data from the factory to generate the scheduling data for the group of machines.

The data collected from the factory by the means for collecting data 10 is described in more detail below in relation to FIG. 3. In the example shown in FIG. 1, the computer system 1 is located remotely from the factory 4, such as in a cloud. Alternatively, the computer system 1 may be located at the factory 4.

In an alternative embodiment, the method steps described herein in generating the schedule for the group of machines may be divided between the computer system 1 and the factory computer(s) 2 which are computers associated with the factory and which may be located at the factory.

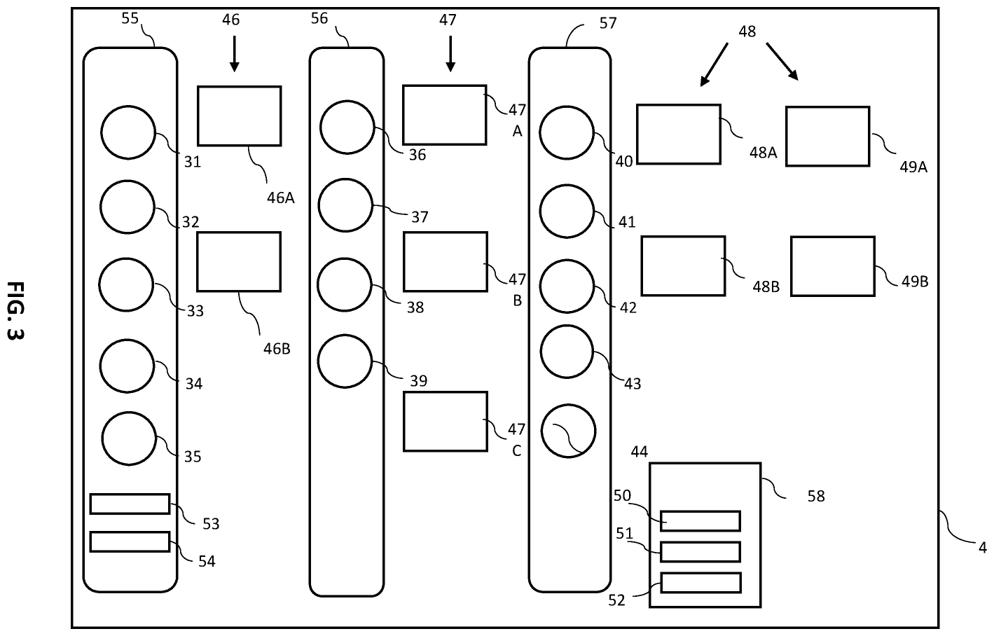

FIG. 2 shows an alternative embodiment of a system 27, in which the method steps described herein in generating the schedule or scheduling data for the group of machines are performed by a local computer system 20 located at the factory 4. The local computer system 20 comprises one or more computers. FIG. 2 also shows the groups of machines 46, 47, 48 the user interface(s) 8, the means to transmit control signals 9, the means for collecting data from the factory 10, and the means for sending data to the computer system 11, which are described in more detail in relation to FIG. 1.

FIG. 3 illustrates some of the machines, products and resources that are located in the factory 4. The factory 4 may manufacture semiconductor devices. In reality the factory will have many more machines products and resources than are shown in FIG. 3.

The products in the factory may be semiconductor wafers, 31, 32, 33, 34, 35, 36, 37, 38, 39, 40, 41, 42, 43, 44. The factory has different machines 46A, 46B, 47A, 47B, 47C, 48A, 48B, 49A, 49B, which are grouped into a first group of machines 46, a second group of machines 47 and a third group of machines 48, although it will be appreciated that the factory may just comprise one group of machines, or many more groups of machines. At least one or the groups of machines or all of the groups of machines may have a schedule generated for them in accordance with the method described herein. The machines perform tasks on the products 31, 32, 33, 34, 35, 36, 37, 38, 39, 40, 41, 42, 43, 44. Each task is a manufacturing step in manufacturing a product. Each product requires a sequence of tasks to be performed on it to manufacture the product. Some additional tasks in the factory may be performed by people working in the factory, such as a task of moving the products between the machines.

The products may be located on racks 55, 56, 57 while they wait for their next task to be performed. FIG. 3 shows products 31 to 35 located on a first rack 55 near the first group of machines 46, products 36 to 39 located on a second rack 56 near the second group of machines 47, and products 40 to 44 located on a third rack 57 near the third group of machines 48. There will also be an additional rack for products located near the machines 49A. 49B, although this rack is not shown in the figure. Although not shown in the figure, the products may also be transported around the factory to different locations within the factory using an Automated Machine Handling System (AMHS).

Depending on the task to be performed, a machine 46A, 46B, 47A, 47B, 47C, 48A, 48B, 49A, 49B, may require additional resources to carry out a particular task. For example, a photolithography machine may require a particular mask or reticle 50, 51, 52, 53, 54 to carry out a particular photolithography task. The additional resources may be located in storage in the factory, for example the reticles may be stored in reticle stockers, which are automated machines that store, clean and retrieve the reticles, or in reticle libraries 60, or they may be located at other locations in the factory such as in a container 58. The additional resources may be transported around the factory using the AMHS. The additional resources required to perform the tasks may also include chemical gases that are used, for example, in implantation, or gold which is required for some specific tasks.

The grouping of the machines will now be explained. In FIG. 3, the first group of machines 46 has a first machine 46A and a second machine 46B; and the second group of machines 47 has a first machine 47A, a second machine 47B, and a third machine 47C. Within a group of machines, the machines can all be the same type of machine, for example each machine 46A, 46B, in the first group of machines 46 is a furnace machine which heats the products.

Even if the machines in a group are all the same type of machine, they may be programmed with different recipes, for example one of the machines may be programmed to perform certain tasks on the products faster than other machines within the same group. Variations in speed between the different machines may also occur depending on the make/model of the machine and the cumulative operating hours of the machine. This means that there are reasons for choosing one machine over another for a particular task within the same group. This grouping of machines is effective when the machines are not involved in constraints that couple many sequential steps.

Alternatively, within a group of machines, the machines can be different types of machine with the machines in the group being coupled together by at least one operational constraint such as a time link constraint, discussed further below in relation to FIG. 5, a maximum number of products which can be operated on by the group of machines, a Kanban process flow constraint or where there is a high degree of re-entrancy between the machines in the group to perform successive tasks on a product.

For example, a group of machines 48 includes a first machine 48A, a second machine 48B, a third machine 49A, and a fourth machine 49B. The first and second machines 48A, 48B may be photolithography machines which perform photolithography tasks, and the third and fourth machines 49A, 49B may be etching machines which perform etching tasks but the machines are all grouped together as a single group 48 since there is a high degree of re-entrancy with a product moving between the machines 48A, 48B, 49A, 49B, multiple times in order to complete a sequence of tasks in its manufacture. However, in most embodiments, groups of machines will include only one type of tool, so for example a group of photo tools or a group of etching tools or a group of furnaces. In another example, a first machine group would be wet benches or cleaning machines while a second machine group would be furnaces and products would have an associated time link constraint for operations performed in sequence by these groups of machines (for example, a product might first need to be cleaned before it is placed in a furnace, but this would need to happen within a constrained period of time once the process has been started by cleaning the product).

As described above, the system may comprise a means for collecting data from the factory 10. The data collected from the factory may convey the tasks to be performed by the group of machines. The tasks to be performed by the group of machines may depend on the products which are waiting to have their next tasks performed on them by the group of machines and/or on products which are being transferred, for example by an AMHS in the factory, to the group of machines so that their next task can be performed by the group of machines. For example, in FIG. 3, the products 31 to 35 are waiting to be processed by the first group of machines 46 so the tasks to be scheduled on the first group of machines 46 will include the next tasks required in manufacturing the products 31 to 35. The tasks to be scheduled on the first group of machines 46 may also include products which are in transit to the group of machines 46 and which have a predicted transit time for arriving at the rack 55. The products in transit may be being transported around the factory by humans, robots or an AMHS.

The data collected by the means for collecting data from the factory 10 may further comprise a location or locations of the products 31 to 44 in the factory, a location or locations of additional resources, such as the reticles 50, 51, 52, 53, 54, required by the or each group of machines 46, 47, 48, a location of or locations of one or more containers 58 in which the products and/or the additional resources are contained, wherein the one or more containers 58 may comprise PODs in which the reticles are placed while they are being transferred to different locations around the factory, an estimated transit time for an AHMS in the factory to transfer one or more products and/or one or more additional resources to the or each group of machines in the factory, a priority of each product or task; preferences of which machines to use per product per process step and recipes of the machines; which recipes are active in each machine; maximum volume of products to be processed in a machine or in a zone of process steps.

The data collected by the means for collecting data from the factory 10 may additionally or alternatively comprise an operational status of at least one or all of the machines 46A, 46B, 47A, 47B, 47C, 48A, 48B, 49A, 49B, in the factory, such as whether or not a machine is working and/or details of the tasks that the machine is capable of performing.

In order to collect the data, the means for collecting data from the factory 10 may comprise the necessary components to collect the data such as a tracking system, sensors, bar codes, and radio frequency identification tags. The means for collecting data from the factory 10 may comprise components of at least one or all of the machines in the factory.

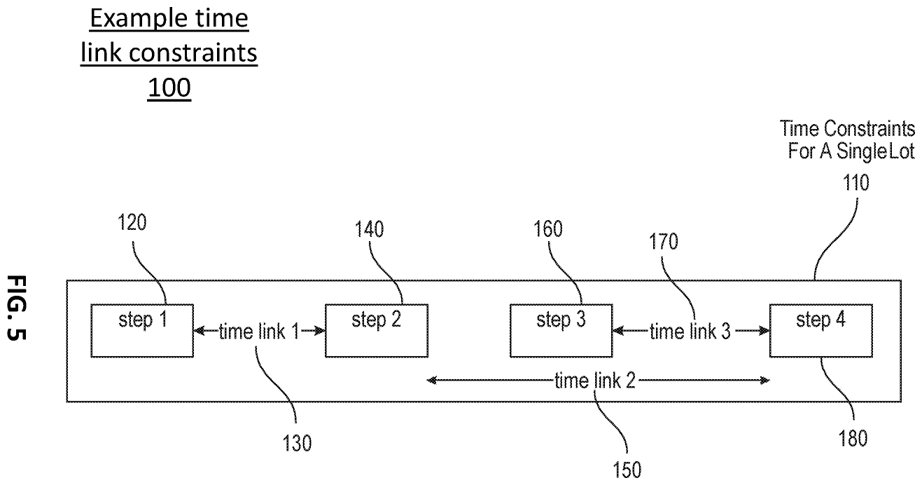

FIG. 4 shows an example of movement of a product, such as one of the semiconductor wafers 31 to 44, as it is moved between different machines in the factory. The product is shown to first have a task 401 performed on it by machine 47A. The product is then moved to a next machine 48A which performs a task 402 on the product. The product is then moved to machine 49B which performs the next task 403 on the product. The product is then moved to machine 48B which performs the next task 404 on the product. The tasks 401 to 404 form a sequence of manufacturing steps in manufacturing the semiconductor wafer.

FIG. 4 also illustrates idle time 405, which is time when the machine is not working to perform a task. The product can be moved manually between the machines or by robots within the factory.

Referring to FIGS. 5 to 15, a specific embodiment and several alternative embodiments will now be described with reference to each Figure in turn. With reference to FIG. 5, an embodiment where time constraints for a single lot 100 are shown will now be described in more detail.

A series 110 of tasks 120, 140, 160, 180 are shown that need to be completed in a certain order. Some of these tasks need to be completed within a certain time of each other, which is shown using “time links” 130, 150, 170 that link some of the tasks 120, 140, 160, 180 together. In this example, the first task 120 is time linked 130 to the second task 140 meaning that the second task 140 needs to be completed within a certain predetermined time of completion of the first task 120. Similarly, in this example, there is a time link 150 between the second task 140 and the fourth task 180 and another time link 170 between the third task 160 and the final task 180.

Time links can also be referred to as QTime links or constraints and can be considered time constraints or time limits between the performance of manufacturing steps.

A lot is typically the term used to describe a particular series of related tasks that results in the manufacture of a particular product or end product.

In embodiments, such as embodiments used in semiconductor wafer fabrication plants, time links between tasks can be a critical part of the manufacturing process because they ensure the quality of the end product. The violation of a time link can result in a minor or major re-work, or even scrap, of the product due to compromised material—for example due to oxidisation because too much time elapsed with the product in a semi-completed state and in a state not suitable for prolonged exposure to air. Typically, wafers in a fabrication plant need to be routed through a series of machines each of which perform each of the tasks (e.g. tasks 120, 140, 160, 180) so time links can involve several consecutive toolsets/machines. Time links can also be nested and/or chained together.

Where multiple time links are relevant to a series of tasks, a time link “tunnel” may be formed of a series of tasks having multiple coupled time links between these tasks.

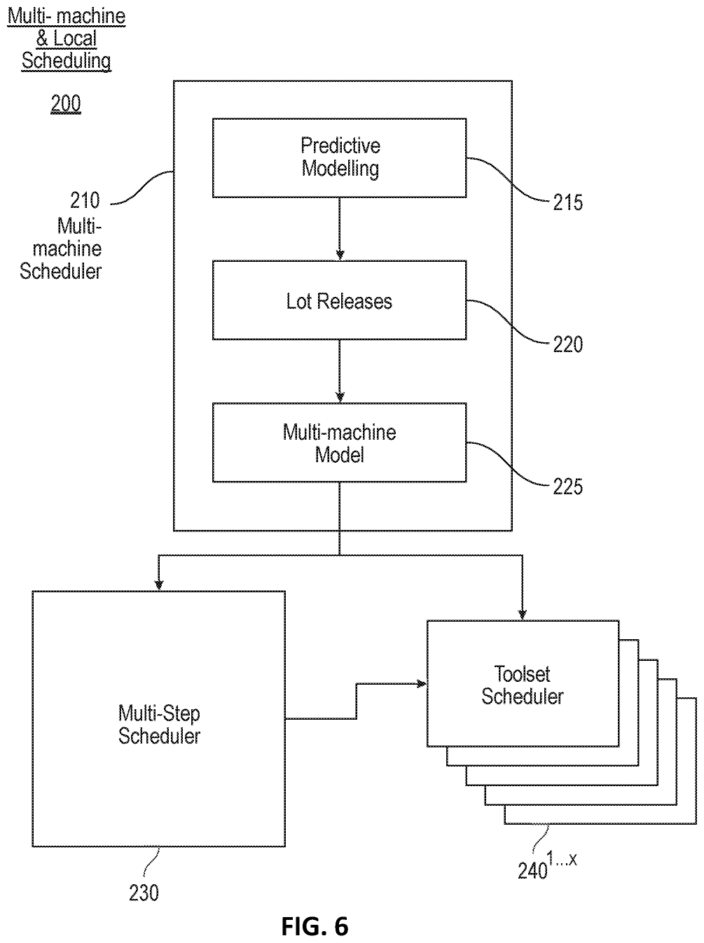

With reference to FIG. 6, an embodiment where a multi-machine and local scheduling approach to scheduling (for example in a wafer fabrication plant) are shown will now be described in more detail.

In this embodiment the fab-wide scheduler 210 provides scheduling data to both multi-step scheduler(s) 230 and toolset schedulers 240.

The approach of this embodiment uses a multi-machine scheduler 210 (alternatively known as a fab-wide scheduler), a multi-step scheduler 230 and a plurality of toolset schedulers 240¹ to 240^{x}. In other embodiments (not shown in the Figure) there may be more than one multi-step scheduler 230 and in further embodiments there may be only one or more multi-step schedulers 230 or one or more toolset schedulers 240.

The multi-machine scheduler 210 (alternatively known as a fab-wide scheduler) uses a high-level optimisation model with a long time horizon to provide inputs and targets to the toolset schedulers 240¹ to 240^{x} and the multi-step scheduler 230. Inputs, depending on embodiment, can include any or any combination of priorities of products; priorities of wafers; ranking of products; ranking of wafers; WIP targets; and/or toolset and product restrictions. In other embodiments the multi-machine scheduler 210, in particular the multi-machine model 225, uses a modified version of the shifting bottleneck heuristic considering product routes, processing capacity of toolsets, transition times between toolsets and given due dates of the end products. In other embodiments, the multi-machine model 225 uses a flow control model (based on a relaxed MILP model as described elsewhere in this specification). In further embodiments, the multi-machine model 225 uses an iterative heuristic, using dispatching rules modifying priority weights in an iterative fashion.

In embodiments, the high-level optimisation model can be generated and updated based on historical data for the manufacturing facility for which it models.

The multi-step scheduler 230 schedules lots having multiple tasks per lot while the toolset schedulers 240¹ to 240^{x} each schedule a specific tool. The output of the multi-step scheduler 230 can output lots or tasks to one or more of the toolset schedulers 240¹ to 240^{x}. In other embodiments the multi-step scheduler 230 operates independently of the one or more toolset schedulers 240 and provides scheduling or scheduling data directly to manufacturing tools/machines.

The multi-step scheduler 230 is detailed optimisation-based solution that considers many future process steps. It has a longer-term view than the toolset schedulers 240¹ to 240^{x} and encompasses many toolsets in the same model. It does not consider the whole manufacturing facility/fabrication plant within which it operates in the same model. If the coupling between many toolsets is too large, optionally the steps would be broken up into smaller sets of steps in order to make the optimisation tractable.

The multi-step scheduler 230 would for example be used with toolsets having a high degree of re-entrancy between few successive steps (e.g. three photolithography process steps where the first and third steps are performed by the same tool and a second tool performs the other step) or with toolsets that are coupled by complex constraints such a Kanban process flow constraint or time link tunnels across few successive steps.

In embodiments, a lexicographic objective function is used by the multi-step scheduler 230 to optimise these complex constraints. This can be especially suited for this use because the function can quickly determine the optimal minimum number of time link violations that could occur.

In embodiments the solution strategy used by the multi-step scheduler 230 uses two phases: a constructive phase (termed job decomposition) then an improvement phase (termed stage decomposition).

In this embodiment, the multi-step scheduler 230 begins by processing the suggested input of the current state of the manufacturing facility/semiconductor fabrication plant (depending on where it is being used), along with any auxiliary scheduling inputs such as the output of the multi-machine scheduler/fab-wide scheduler 210 (for example: any new priorities; any critical ratio(s) and/or line balancing factor(s); priorities of products; priorities of wafers; ranking of products; ranking of wafers; WIP targets; and/or toolset and product restrictions).

Then, a multi-step solution strategy is executed, which considers the entire planning horizon. For each lot, the entirety of its time link tunnel is scheduled so that the beginning of the time link is planned according to the later steps. If the earlier steps are started immediately, and it is not possible to schedule the later steps such that the time links are met, then the earlier steps need to be re-planned.

The schedule is constructed using optimisation approaches to ensure that all time link violations are minimised (for example by using job decomposition where lots are scheduled in groups ranked according to how important they are).

Subsequently, the schedule is improved upon using optimisation approaches to ensure that no time link or Kanban violations are introduced from the original schedule, and secondary target outcomes (for example cycle time, on-time delivery and/or batching efficiency) are minimised/met as appropriate.

By using a highly-distributed cloud platform in some embodiments, or a sufficiently computationally powerful computer system, many similar solution strategies can be simulated in parallel with subtly different tuning parameters. Of the final results that these simulations produce, they can be compared using predetermined assessment criteria for schedule quality and the substantially optimal/best schedule is selected for use to manufacture the products. Such a highly-distributed cloud platform can be used to provide any or any combination of: the fab-wide scheduler 210; one or more multi-step schedulers 230; one or more toolset schedulers 240.

This approach can allow optimisation within constraints such as time link and Kanban constraints. Kanban constraints involves limiting the processing of products to a certain route (i.e. sequence of machines) or in a specific machine. Optimisation approaches such as mixed integer programming (MILP) models and/or constraint programming (CP) models can be used in some embodiments, but other optimisation approaches can be used in other embodiments.

In some embodiments, to generate a fab-wide schedule and/or a multi-machine schedule and/or toolset schedules (terminology dependent on embodiment), where the schedule determines the allocations of products/wafers to machines, and detailed resource allocation in certain embodiments the following approach is used:

First a single multi-machine/fab-wide schedule is created for all products and resources. This can include scheduling for any or any combination of placeholders of reticles; reticles (masks required for photolithography); automated material handling systems (e.g. robotics to transfer products and other secondary resources between locations/machines).

Second, events for planned maintenance of machines or components of machines are generated/simulated.

Third, other resources are scheduled simultaneously with the scheduling in the first step, including: storage equipment (for example, for wafers, this could include a wafer stocker and/or bins); reticles (for example this could include reticle stockers and/or reticles assigned to bins).

Fourth, a multi-machine schedule (or fab-wide schedule) is generated which is generated considering all of the resources and products simultaneously to achieve substantially optimal production. In some embodiments the output schedule is used by the control systems for the plurality of machines/the fabrication plant/the manufacturing facility (which may have a central control system or control systems distributed across the plurality of machines) that handle the materials. In other embodiments, the schedule is converted into scheduling data (e.g. priorities and/or scheduling windows alongside tasks) that is then used by multi-machine schedulers and/or toolset schedulers to generate schedules for multiple manufacturing tools/machines or single types of manufacturing tools/machines respectively. For example, in a 300 mm wafer fabrication plant, where machines/robots manage the material, the signals generated by the fab-wide schedule allow the machines/robots to execute their operations based on these signals. In another example, in a 200 mm wafer fabrication facility, operators execute the instructions in the schedule provided through the signal being sent to a Manufacturing Execution System (MES) and/or dispatching software/system(s).

In step 215, the fab-wide scheduler 210 performs predictive modelling using historical data relating to the factory or portion of a factory being modelled, so for example using historical data for a group of manufacturing tools and/or machines. The predictive model 215 also takes as inputs the current state of the manufacturing tools/machines and the products and/or associated sequence of manufacturing steps required to manufacture those products along with any constraints/priorities associated with either the products/steps. For these inputs, the model 215 generates a prediction of the distributions (or in other embodiments, uses a model to output a distribution based on historical and/or current data) of any or any combination of (a) the processing times; (b) the transfer times (e.g. the time to move a product/resource between machines or in/out of storage); (c) the time to failure (e.g. for each machine, to predict when any disruption to availability of each, a group or all machines might occur); (d) the time to recovery (e.g. how long it might take to repair/replace a failed machine should failure occur). In embodiments, the model(s) 215 will generate results even if some input parameters are missing. In at least some embodiments, the distributions are used to create tests (for example via simulations) of discrete parameters that would be used for future predicted distributions and this is output from the predictive model 215 to the lot release process 220. The output from the predictive model 215 is a set of lots, where each lot represents a product or group of products to be manufactured along with the respective priority of manufacture of that lot and any constraints associated with that lot, the products within that lot or the sequence(s) of tasks within that lot, and the predicted distributions.

The lot release process 220 takes the outputs of the predictive model(s) 215 and ranks the input lots, selects a number of the highest ranked input lots and performs a plurality of simulations of the scheduling of the selected lots using the predicted distributions, where each simulation uses different values from the predicted distributions. This allows simulation of a variety of conditions/states in the factory, for example to assess different schedules under situations where different manufacturing machinery fails and/or where the time needed to process or move lots around the factory differs, using the predicted distributions from the predictive model 215. The output from the lot release is a probability for each simulation and then also across simulations of any breach of constraints, for example breaches of time links (known as scheduling violations). Depending on a user-determined value provided for an acceptable level of violations per lot output from the simulations, lots that breach the acceptable pre-determined threshold for violations per lot (i.e. are above the acceptable level of violations per lot) are removed from the lots to be scheduled by the lot release process 220. In other embodiments, instead of removing lots from being scheduled, a priority value is allocated to these lots that allocated a very low priority, thus almost guaranteeing that the lot will not be scheduled to avoid a breach of the time links for that lot. In another embodiment, the lots are not scheduled but bypass the multi-machine model 225 and are allocated the lowest possible priority or a soonest start time that is far in the future. The output from the lot releases 220 can be the lots selected for scheduling, or all lots but where lots determined to exceed the acceptable threshold for violations per lot are allocated a low priority. In some embodiments, the lot release process 220 is only performed on lots that will be completed, or are indicated from input data should be completed, within a certain time frame (e.g. the next 24 hours, or a certain number of days, or a certain number of weeks). In some embodiments the ranking is performed based on start times and/or end times for tasks or products within each lot; and/or on bottlenecks in the factory/fabrication plant.

The multi-machine model 225 takes the lots input from the lot release process 220 and prepares a manufacturing schedule for the lots. In one embodiment, the multi-machine model 225 prepares a schedule using a heuristic scheduler (also referred to as an iterative simulation). The heuristic scheduler considers multiple future steps, calculates the total waiting time of a lot for its next steps and calculates a score indicative of how much bottleneck is anticipated for its next steps. Then, the weights used for scheduling are modified iteratively to force the lot to follow a different route (e.g. using different machines, or performing steps with different start times or finish times or in different orders where possible) or to reprioritise a lot compared to other lots to either benefit that lot or the other lot(s). The total objective function is then evaluated in each iteration to determine if a better average cycle time across the lots from the lot release is achieved. The final output is a schedule for all of the input lots, across all manufacturing tools/machines/resources in the factory/fabrication plant.

In other embodiments, the multi-machine model 225 uses a multi-integer linear programming model. In embodiments, this MILP model is a flow control model based on a relaxed MILP approach (where for example some constraints are relaxed). Again, the output is a schedule for all of the input lots, across all manufacturing tools/machines/resources in the factory/fabrication plant. In some embodiments the MILP model considers time intervals such that, in each time interval, a determination is made of which jobs to start considering the capacities of the manufacturing tools/machines and other operational and/or physical constraints (for example resources).

The multi-machine model 225 then converts the determined schedule into at least a set of tasks for the manufacturing tools/machines/resources in the factory/fabrication plant along with priority values for all of these tasks. In some embodiments, the conversion process also generates any or any combination of: an earliest start time for a task; a latest start time for a task; task details. In some embodiments the priority value can be a relative value (i.e. indicated the relative priority of each lot to other lots) or a weight. The output of the multi-machine model 225 is the set(s) of tasks and the associated priorities, and in some embodiments the earliest start time for task(s) and/or the latest start time for task(s) and/or task(s) details. These outputs are provided to the multi-step scheduler(s) and/or toolset scheduler(s).

The fab-wide scheduler 210 in some embodiments also takes into account the resources required for the manufacture of lots, for example such as buffer release (where resources are released from buffers, the buffers providing intermediate storage of part-finished products, to enable the manufacture of lots by further completing or completing the manufacture of part-finished products).

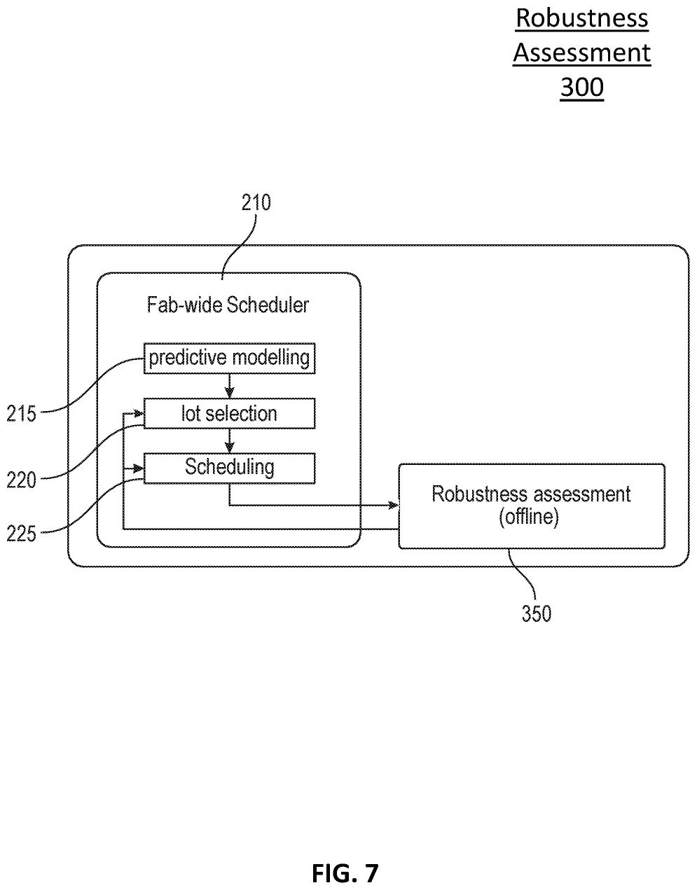

With reference to FIG. 7, an embodiment where a robustness assessment approach 300 is shown will now be described in more detail.

The output of the multi-machine model 210 (which in embodiments can also be known as the fab-wide scheduler or global scheduler) is used as an input into a robustness assessment module 350 which conducts offline simulations to verify that the output of the fab wide model would not cause any rework.

Various scenarios are simulated by the robustness assessment module 350 using a conservative dispatching model. If there are time link violations above the expected and/or accepted risk/tolerance for violations, then feedback is given to the multi-machine scheduler 210, in this embodiment to the lot selection module 220 which determines lot releases and to the scheduling module 225 which implements the multi-machine/fab-wide solution, to reduce the risk of time link violations. A new multi-machine/fab-wide scheduling run/iteration is thus triggered should the time link violations exceed the expected and/or accepted risk/tolerance for violations.

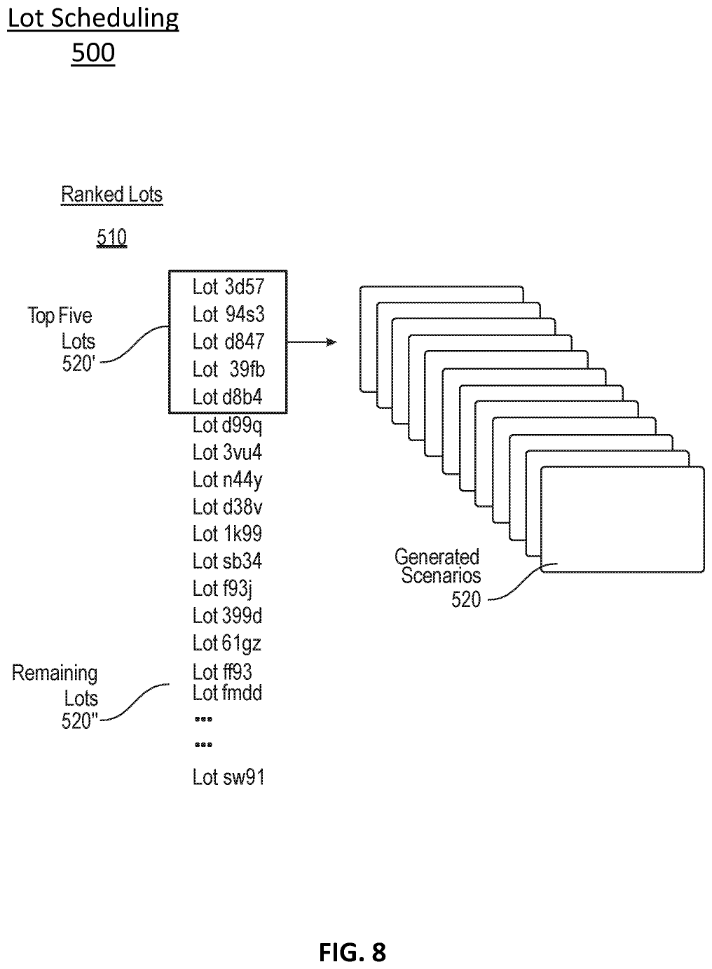

With reference to FIG. 8, an embodiment where a lot scheduling approach 500 is shown will now be described in more detail (process 220 as previously described in FIGS. 6 and 7).

The lots to be performed by the multiple machines are ranked into ranked lots 510 according to a set of predetermined rules, for example ranking first by any deadlines associated with lots/end products and then by any priority value(s) associated with lots/end products.

In this embodiment, the top five lots 520′ are selected to determine a substantially optimum order in which to perform the lots 520′. In other embodiments, different numbers of lots can be selected. The remaining lots 520″ are left in the list of lots to be performed in future for assessment in future iterations of the process.

For the selected top five lots 520′, a number of simulations are performed to generate a set of scenarios 520 for performing the top five lots 520′ in different sequences.

In an embodiment deployed in a wafer fabrication facility, a number (n) of fab-state scenarios are created using Monte-Carlo methods from the distributions of: processing times; transfer times; time to failure (of machines in the fab) and time to recovery (of machines in the fab). Following this, a number (n) of schedules are generated using a computationally fast heuristic scheduler. In other embodiments, deployment can be in manufacturing facilities other than a wafer fabrication facility and therefore manufacturing-facility-state scenarios are created in place of fab-state scenarios. In this embodiment, n=1000 but in other embodiments different numbers of scenarios and/or schedules can be created. The predictive modelling in this embodiment can estimate the profiles of the uncertain parameters such as processing times, transition times, tool time to failure and time to recovery.

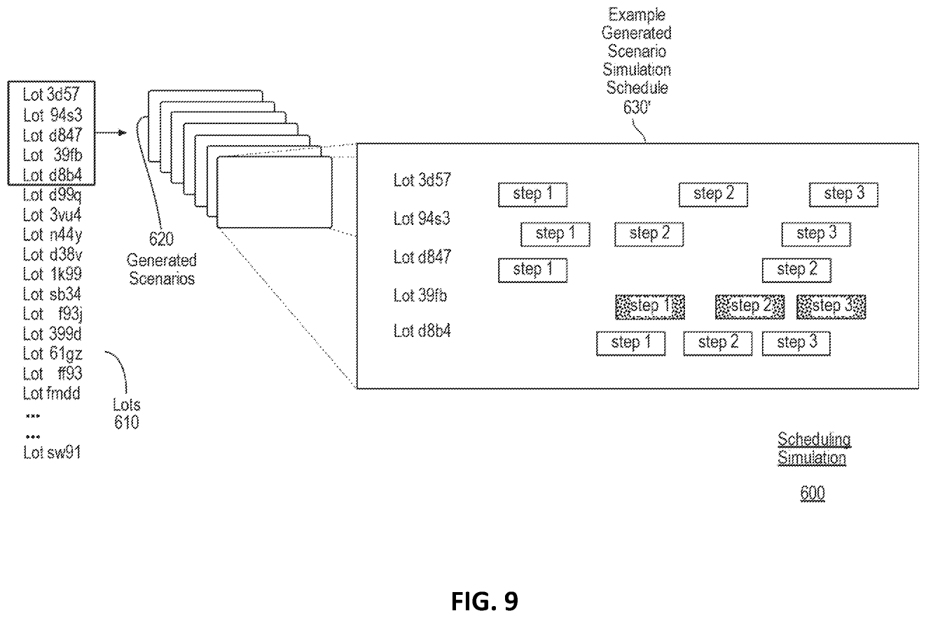

With reference to FIG. 9, an embodiment where a scheduling simulation 600 is shown will now be described in more detail.

An example generated scenario 630′ of a set of generated scenarios 620 is shown in FIG. 9, having a series of steps to be performed for each lot shown scheduled in sequence for each lot and the jobs for each lot shown in parallel against those of other lots.

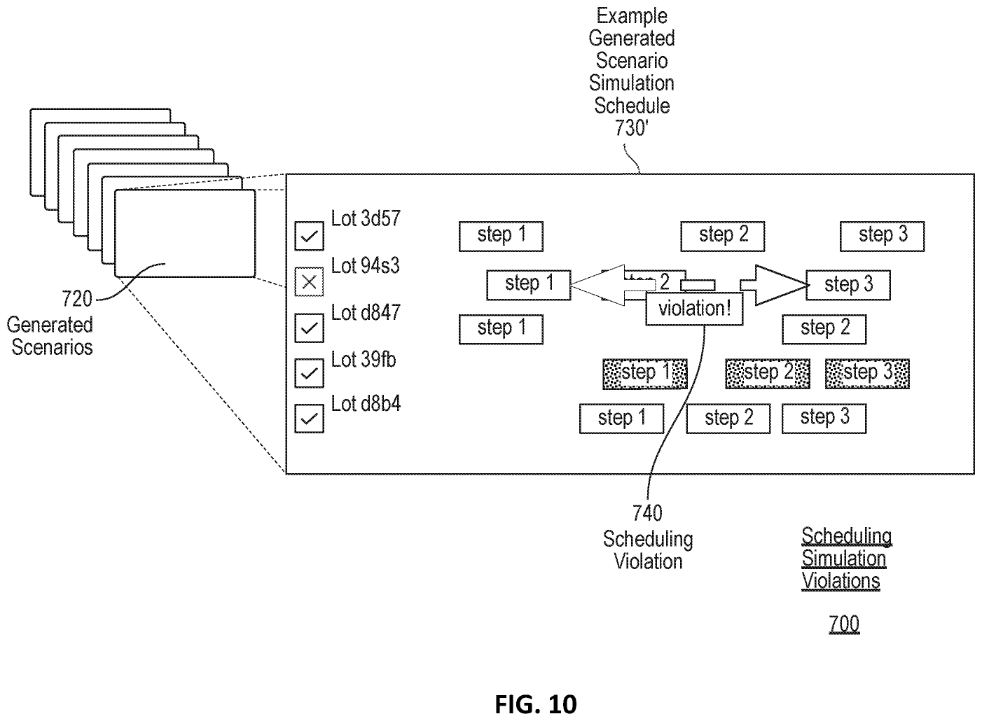

With reference to FIG. 10, an embodiment where determining scheduling simulation violations 700 is shown will now be described in more detail.

For an example generated scenario simulation schedule 730′, any violations 740 in time links for a lot can be determined, so for example any times that would elapse between the performance of jobs in a lot that would result in either a time link to be exceeded or in a time link to be exceeded beyond a predetermined tolerance level of time link compliance/lot selection tolerances (which tolerance can be set at a fab/manufacturing facility level).

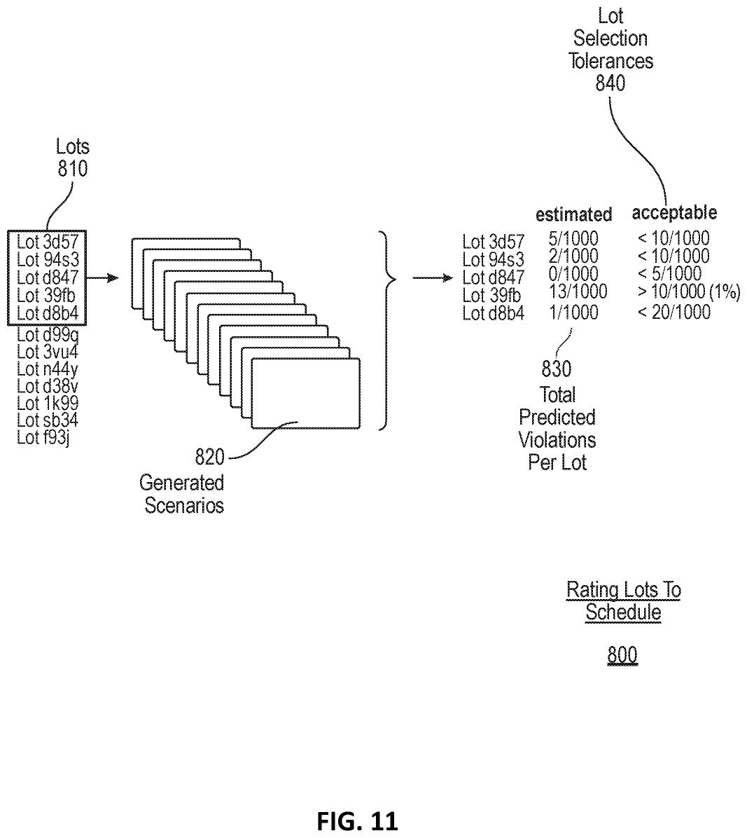

With reference to FIG. 11, an embodiment where an approach to choose lots to schedule 800 is shown will now be described in more detail.

For each of the generated scenarios 820, a total predicted number of violations per lot 830 is generated and this can be assessed against the lot selection tolerances 840 in order to determine whether to schedule each lot based on that generated scenario. Those lots that exceed the acceptable lot selection tolerances 840 can remain unscheduled until the next iteration of the process. In alternative embodiments, these lots can be output for scheduling but allocated a low priority to prevent their being scheduled, or alternatively provided with a earliest start time sufficiently far in the future to prevent their being scheduled.

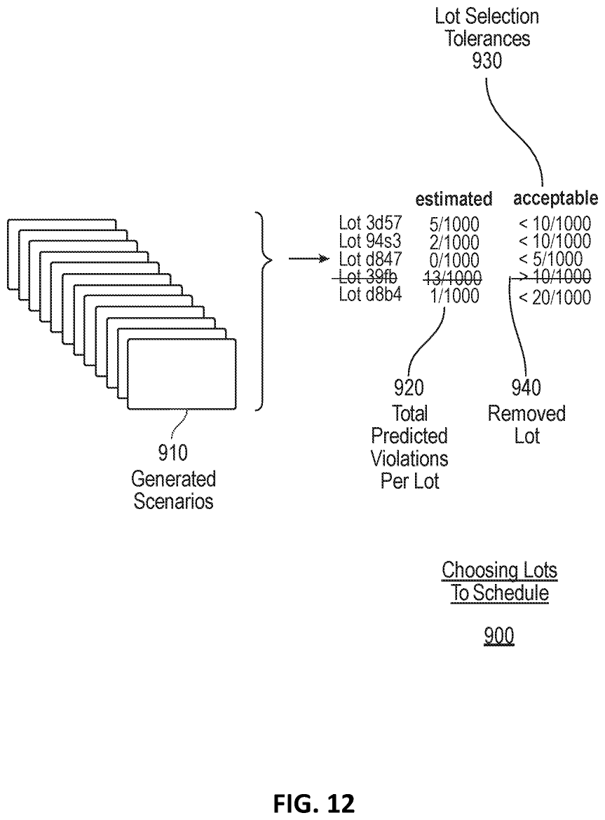

With reference to FIG. 12, an embodiment where the chosen lots to schedule 900 are shown will now be described in more detail.

The output from the process shown in FIG. 9 is that, based on the total predicted violations per lot 920 for each or multiple generated scenarios 910 measured against the lot selection tolerances 930, some lots are removed 940 from the list to be scheduled. In alternative embodiments, instead of being removed from the list to be scheduled these lots can be output for scheduling but allocated a low priority to prevent their being scheduled, or alternatively provided with a earliest start time sufficiently far in the future to prevent their being scheduled.

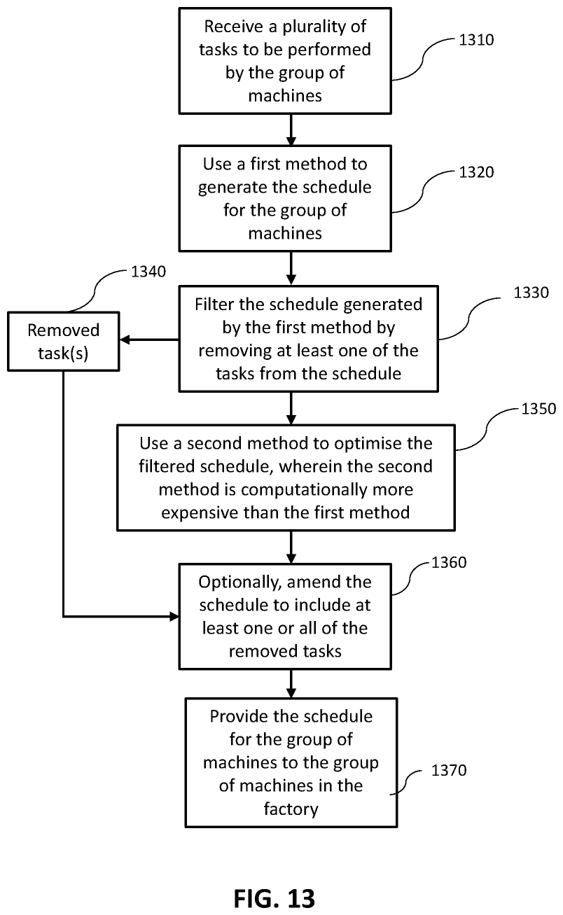

FIG. 13, illustrates computer-implemented method steps which are used to generate a schedule for a group of machines, such as the first group of machines 46, the second group of machines 47 and/or the third group of machines 48 discussed above, in accordance with an embodiment of the present invention.

In step 1310, a plurality of tasks to be performed by the group of machines is received. The plurality of tasks may be conveyed in data collected by the means for collecting data from the factory 10.

In step 1320, a first method is used to generate a schedule for the group of machines. The schedule generated by the first method is a provisional schedule which is later modified by other steps in the method before being provided to the group of machines in the factory. The schedule in step 1320 allocates one task of the plurality of tasks or a time-ordered list of some of the plurality of tasks to each machine in the group of machines.

The first method in step 1320 may comprise using heuristic rules, dispatch rules, constraint programming, discrete time simulation (which include dispatching rules), or a previously-generated schedule of tasks for the group of machines.

In step 1330, a second method is used to optimise the schedule generated by the first method in step 1320. The second method could also be referred to as the optimising method and it produces an optimised schedule for the group of machines.

The second method may optimise the schedule for key performance indicators in the factory. Optionally, the first method may optimise the schedule for key performance indicators in the factory. The first method and the second method may optimise the schedule for the group of machines using the same key performance indicators.

The key performance indicators may include one or more of the following: an engineering quality; a speed of production; a cost of production; a throughput of production; a minimum number of violations to time link constraints (a minimum number of violations may be unavoidable, so this may be treated as a soft constraint which is allowed to be violated and modelled by heavily penalising their violation in the method); a magnitude of a violation of time link constraints; a batching efficiency weighted by tool, to model the relative cost to the factory of running batches on certain tools over others, and to allow the optimizer to distinguish worsening the batching efficiency at upstream toolsets to realise even greater gains at the more expensive downstream groups of toolsets and minimising the queueing time of lots (this naturally translates into a reduction in cycle time which is often a factory's key objective). The second optimising method may minimise an objective function.

In one embodiment, the optimising method may ensure that all time link violations are minimised, for example by using job decomposition where lots are scheduled in groups ranked according to how important they are. The optimising method may ensure that no time link or Kanban violations are introduced, and that secondary target outcomes, for example cycle time, on-time delivery and/or batching efficiency, are minimised or met as appropriate.

This approach can allow the second method to optimise the schedule for the group of machines within constraints such as time link and Kanban constraints. Kanban constraints involve limiting the processing of products to a certain route, i.e. a sequence of machines or in a specific machine.

The second method may comprise Mixed-Integer Linear Programming or constraint programming or any other complex exact mathematical method or advanced heuristic or metaheuristic method. The second method may be computationally more expensive than the first method.

The first method and/or the second method in steps 1320 and 1330 may use data collected from the factory by the means for collecting data from the factory 10 in generating the provisional schedule and/or in optimising the provisional schedule. The data collected from the factory is discussed in more detail below, and in relation to FIG. 3.

The optimised schedule for the group of machines produced by the second method in step 1330 may be provided to the group of machines in the factory in step 1350. Alternatively, the optimised schedule for the group of machines may be amended based on additional information in step 1340 before it is provided to the group of machines in the factory in step 1350. The schedule for the group of machines may be amended in step 1340 in view of the filtering processes, and/or or based on updated data.

If the method of FIG. 13 is provided with the systems described above in relation to FIGS. 1 and 2, then it is noted that the steps of generating the schedule for the group of machines, including the step of using the first method to generate the schedule for the group of machines in step 1320, using the second method to optimise the schedule in step 630, and optionally amending the schedule in step 1340, may be performed by the computer system 1 or the local computer system 20.

Providing the schedule to the group of machines in the factory in step 1350 may comprise providing the schedule on one or more user interfaces 8 in the factory. Alternatively or additionally, providing the schedule to the group of machines in the factory may comprise using the means to transmit control signals 9 to automatically operate the machines in the group of machines in accordance with the schedule, and/or to automatically operate processes in the factory to enable the machines to operate in accordance with the schedule for the group of machines.

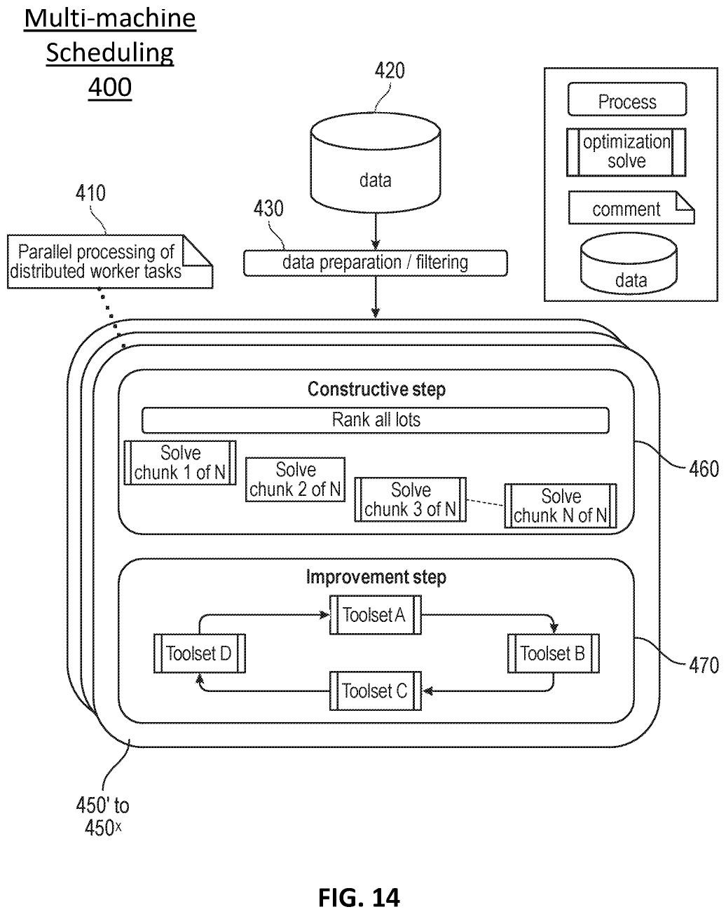

With reference to FIG. 14, an embodiment where a multi-machine scheduling approach 400 is shown will now be described in more detail.

At least some embodiments consider scheduling in manufacturing facilities such as semiconductor wafer fabrication plants using multi-objective batch scheduling (of a complex flexible job shop problem). In these embodiments, batches have different operating costs and consecutive steps of a job are constrained with time links.

Several other process aspects arise in manufacturing settings such as semiconductor wafer fabrication facilities, such as: flexible machine downtime; incompatible job families; different job sizes and parallel machines being operated.

The aim of at least some embodiments is to minimise any or any combination of: the total weighted batching costs; queuing time; and the number of violations of time link constraints.

In the described embodiment, in relation to FIG. 14, a two-stage solution strategy is set out, which combines mixed integer linear programming (MILP) models and heuristics. At a high level, the approach of this embodiment can be broken down into “constructive” and “improvement” steps. There can be significant improvements in scheduling when using the approach of this and other embodiments described in this specification.

For most manufacturing concerns, especially very capital intensive industries like multi-billion dollar wafer fabrication plants, utilisation of the manufacturing capabilities must be optimised and so these types of facilities tend to operate around—the clock. Adding significant new capacity can take years and investments of billions of dollars, so one of the best ways to meet increasing demand with current resources is to cultivate efficient production processes in order to decrease production costs and increase the time to market ratios. Efficient production control and advanced scheduling are vital in these types of industry as a method to increase throughput, reduce queuing time and reduce re-work and scrap.

In the present embodiment, the solution presented will be applied to the industry of semiconductor wafer fabrication. Wafer fabrication is one of the most complicated manufacturing processes in the modern world. A single lot of wafers may go through over 1,000 steps in different work areas resulting in complex constraints and major dependencies. In other embodiments, the solution described can be (adapted and) applied to other industries to generate schedules for substantially optimising production.

Time link constraints (also known as time lags in scheduling literature) occur when a set of consecutive process steps must be completed within a fixed time window. In a highly complex wafer fabrication environment, these constraints add significant complexity; even the most advanced fabs struggle with scheduling time constraints.

A silicon wafer undergoes a fabrication process by entering multiple production steps, where each step is performed by different, highly sophisticated tools. Optimising the transition and waiting time of the lots has a huge impact not only on a fab production performance but also on its profitability. As an example, by introducing time constraints at the wet etch and furnace process steps, manufacturers can prevent the likelihood of oxidation and contamination. Failing to do so risks contact failures, low and unstable yields, the consequence of which is either re-work, or the wafers must be scrapped. Such problems are difficult to discover during wafer processing, and to run special monitoring lots would be a considerable effort.

Yield optimisation has long been considered to be a key goal, yet difficult to achieve in semiconductor wafer fab operations. As the semiconductor manufacturing industry becomes more competitive, effective yield management is a determining factor to deal with increasing cost pressures.

Time links between consecutive process steps are one of the most difficult constraints to schedule, with a significant impact on yield management. Some factories avoid the problem by dedicating tools to each process group that requires a previous cleaning or etch step. The disadvantage of this strategy is the higher demand from the wet tools, which leads to higher investment, more cleanroom space, and ultimately to lower capital efficiency. The trade-off between increasing throughput and a higher likelihood of violating lots' time constraints is an everyday battle for fab managers trying to meet yield targets.

An example of time constraints for a single lot is illustrated in FIG. 5. It shows a time link system between four consecutive process steps. In this example, we can see that the lot has time links constraining Step 2 to Step 4 as well as from Step 3 to Step 4, with overlapping time link phases. This means that after completing process Step 3, the lot begins a new time link phase (Time Link 3) whilst already transitioning through an existing time link (Time Link 2) started upon completion of Step 2. As you might expect, the need to simultaneously look ahead and consider future decisions whilst also being constrained by past decisions is not trivial to model well in a heuristic or as dispatch rules. Time link constraints are already difficult to navigate, but nesting them adds yet another layer of complexity for heuristics. Different types of time link constraints are analysed and discussed in Klemmt and M″onch (2012) which is herein incorporated by reference into this specification. In FIG. 5, if the final Step 4 cannot be brought forward, scheduling Step 3 too close to Step 2 may make it impossible to meet the “Time Link 3”. This is because the time between Steps 3 and 4 is now greater than the maximum allowed. This would not be a problem if the time link constraints were not nested and we only have to schedule according to the “Time Link 2”.

Time link constraints endorse the necessity for a global fab scheduler (or multi-machine scheduler) as described in this embodiment and in other aspects and embodiments in this specification. These production constraints mean that toolsets become tightly coupled and must be optimised as a single entity. Without doing so, the work in progress (WIP) flow cannot be controlled well and we may end up creating bottlenecks at downstream tools, thus resulting in time link violations due to a queue build-up.

For example, maximising throughput at the upstream toolset may cause too much WIP to arrive at the downstream toolset to process before the time link expires. These lots end up queuing in front of the downstream toolset and ultimately violate their time link due to waiting too long before processing. It is therefore common to see large queuing times of lots at the toolsets where time link constraints commence and very little queue time in front of the remainder of the downstream toolsets.

On one hand, the WIP needs to flow freely through downstream toolsets with minimal queuing however on the other hand, operators cannot afford to be overly conservative and stifle throughput as a result of keeping downstream tools unnecessarily idle waiting for transiting lots. This problem enforces the need for so-called “global” or “multi-machine” scheduling of the fab that considers upstream and downstream toolsets simultaneously.

In at least some embodiments, the global fab scheduling problem is modelled as a complex flexible job-shop-scheduling problem with time link constraints. A flexible job-shop-scheduling problem is an extension of classical job-shop problems that permit an operation of each job to be processed by more than one machine. The described embodiment also considers the important operational sides of the problem: batch scheduling; job incompatibilities; and/or machine downtimes.

Scheduling of semiconductor wafer fabrication is a complex system usually involving multiple and conflicting objectives. The described embodiment provides a method and system for the optimisation of three of the most important objectives in semiconductor industry:
Minimise the number of violations to time link constraints, as violating those constraints might result in rework, scrap or longer cycle time. In some circumstances, due to limited capacity a minimal number of violations may be unavoidable. Therefore, they are treated as “soft” constraints; allowed to be violated and modelled by heavily penalising their violation in the objective function.
Maximise the batching efficiency weighted by tool. This is to model the relative cost to the fab of running batches on certain tools over others. It also allows the optimiser to distinguish worsening the batching efficiency at upstream toolsets to realise even greater gains at the more expensive downstream toolsets.
Minimise the queuing time of lots. This naturally translates to a reduction in cycle time which is often a fab's key objective.

In the described embodiment, the number of late lots deliveries is not optimised as an objective. Instead, a maximum number of late lots is treated as hard constraint such that their number must be no worse than the baseline scenario in all cases.

In semiconductor manufacturing, the effective monetary cost of running a batch of lots can vary greatly across different tool groups. Therefore the described embodiment uses a weighted number of batches where the creation of batches is penalized according to a hierarchy of three costs:
Clean tool (batches are inexpensive)
Cheap furnace tool (batches are typically five times more costly)
Expensive furnace tool (batches are typically ten times more costly)

The described embodiment therefore presents a method of batch scheduling with different batch costs and job time link constraints in a multi-objective approach. Specifically, the described embodiment considers different batching costs. The described embodiment aims to address the optimisation of three of the most important KPIs in semiconductor manufacturing while considering complex process conditions found in wafers fabrication facilities.

The described embodiment solution strategy for solving global scheduling problems consists of a hybrid of MILP models and heuristics. At a high level this strategy can be broken down into two constructive and improvement stages. The constructive step produces a high-quality schedule quickly, typically within 2-3 minutes. The improvement step refines this schedule carefully, leading to a better solution for a further 2-3 minutes. Other embodiments use variations on these specific times as appropriate.

These two steps are encapsulated within a distributed processing environment of multiple threads processing tasks in parallel. The modelled process 400 is showed in FIG. 14 and will now be described in more detail with reference to FIG. 14.

Input data 420 is received by the system, typically relating to the status and current tasks of the machines in the wafer fab, and this input data 420 undergoes pre-processing 430.

In some embodiments the input data can include any or any combination of: a state of the plurality of machines; a state of a fabrication facility: one or more locations of any relevant products; a current task of one or more of the machines; an idle state of one or more of the machines; a maintenance state of one or more of the machines; a demand of one or more of the products; a priority of one or more products; specific due dates of one or more products.

In some embodiments, the pre-processing step 430 can select at least some of the plurality of tasks as a subset of tasks to be used by the one or more simulations to determine a predicted outcome of the subset of tasks to be performed. In other embodiments, the pre-processing step 430 can include any or any combination of: validating the input data quality; reconstructing the input data; combining the input data to generate parameter values.

The constructive step 460 is focused around an iterative process of adding decreasingly important lots into the schedule. All the lots are ranked according to a combination of criteria, q (lot). They are then scheduled in N subsets, a predefined number N of iterations. Higher priority is allowed to jobs with earliest due date, more time link constraints and higher number of steps to be scheduled. This constructive step 460 is a modified version of the extension of the list scheduling procedure Klemmt and M″onch (2012), which is herein incorporated by reference to this specification, where jobs are sorted in non-decreasing order with respect to their due dates. Adding the number of time link constraints and the number of steps to schedule gives a better view on the priority of a job. Increasing the priority of these lots results in scheduling them in earlier iterations where there is more freedom in the schedule. We also ensure to consider all future and time-linked steps of a lot simultaneously in the iteration for which it is selected.

In taking a job decomposition approach, we iteratively solve smaller subproblems where each subproblem contains only a subsets of the total number of jobs. This reduces the total complexity of the problem, which is principally derived by the number of jobs to be scheduled. Subproblems are iteratively solved using MILP.

Adapting the efficient approach of the list scheduling procedure Klemmt and M″onch (2012), the algorithm of this constructive step can be described as follows:
1. Determine the bottleneck toolsets coupled by time link constraints
2. Build an MILP model encompassing these coupled toolsets
3. Rank all lots according to q (lot) in descending order
4. Split the ranked jobs into N chunks of equal number of schedulable steps
5. Solve the MILP problem of each iteration, adding each chunk of jobs in successive iterations

During the iterative solutions of the MILP, jobs of previous iterations are not allowed to move batches however they may still change their timing and/or sequencing. The maximum running time of this stage is evaluated according to the number of jobs to be scheduled. The division of the total time limit is skewed towards earlier iterations as these are typically more complex subproblems to solve due to the ranking criteria of lots. The advantage of this step is the possibility of including all timelink constraints of jobs in each chunk. Otherwise, solving the full problem with coupled timelink constraints for industrial size datasets would not be possible in a reasonable amount of time.

The improvement step 470 is the second and final phase of the solution strategy consists of cycling through the bottleneck toolsets considering one toolset at a time. Given a full MILP model of the entire fab, we only allow decision variables related to the toolset at hand to be modified by the solver in any given iteration. In doing so, the problem size is effectively reduced however we ensure the impact on the timing of the steps on other toolsets is also still considered in the objective function of this toolset.

Furthermore, we allow lots to move within a “close neighbourhood” of candidate batches. This neighbourhood is defined for a given batch B as any other batch B* that has been pre-assigned the same recipe and starts or ends within a minutes of the candidate batch. To simplify this search, batches that are already full on toolsets with a high maximum batch size are considered immutable; their lots are excluded from this local neighbourhood search. We also allow the search to move lots between tools of a toolset.

This improvement step 470 procedure continues iterating until either all toolsets have successfully returned an optimal solution in a single pass or the predefined time limit has been exceeded.

Another facet of this solution strategy 400 is the lexicographic objective function that is used for the MILP model. A linear weighted sum of different objectives is typically how objective functions with many different KPIs are composed. In this instance, however, the objectives have significantly different priorities and having linear weights that are several orders of magnitude different can cause the optimiser to become unstable.

For this reason, in this embodiment the objective function is modified to be hierarchical such that: it optimises a first objective f₁(x) only; then it optimises the second objective f₂(x) such that f₁(x) does not worsen by μ % (typically 0-10%). This is especially useful when dealing with different orders of magnitude in the objective terms of considerably different coefficients because only one sub-problem is considered at a time. This further enables us to model the time link constraints via an objective function penalty term and once the number of time links has been minimised without considering any confounding KPIs, the remaining terms can be optimised given that number of time link violations. Optimising time links is best suited to a lexicographic objective for three reasons:
1. Infeasibility: Should time links be treated as hard constraints, the problem may end up being infeasible due to potential limited fab capacity. Hence we minimise them as part of the objective function instead of disallowing any violations at all.
2. Importance: Additionally, a lexicographic objective gives us the ability to highly prioritise this objective term above all else. Since the cost of violating a time link is so great to a fab (due to potentially scrapping a wafer or performing rework), any improvements in the other KPIs are overshadowed by this term.
3. Automation: The solution of this embodiment is deployed in a live application where the time available for decision making and human interventions is limited, therefore relevant objective preferences should be set up-front and optimised accordingly.

In the described embodiment, the objective function is set up with the following ranking:
1. Above all else, eliminate all time link violations as much as possible
2. Secondarily, maximise the batching efficiency weighted by tool
3. Finally, minimise the queuing time of lots

Notably, solving the problem in this fashion could lead to a situation where the queueing time of lots suffers at the expensive of optimal batching efficiency and time link violations; the solution is not the same as if all terms were optimised together. In using such an approach, we have also considered that the objectives are in order of “freedom”. That is to say that when optimising the third term, a constrained number of time link violations and batching efficiency still allows a large number of solutions to be explored. We have not constrained precise jobs in the way that optimising queueing time (or say, job end times) first would do.

In other embodiments, further fine-tuning the lexicographic order of our objective function can be performed.

As the modelling parameters need to be decided a priori, in the described embodiment parallel computing is used to launch similar computations with subtly different configurations and inspect the results upon completion. Typically we run approximately 10 different parallel threads whose output schedules are assessed according to a success criterion chosen by the parent thread. For example, multiple variations 450′ to 450^{x} can be processed in parallel.

In other embodiments, different numbers of parallel computations can be run in parallel.

In some embodiments there is the additional step of parallel processing of distributed worker tasks 410.

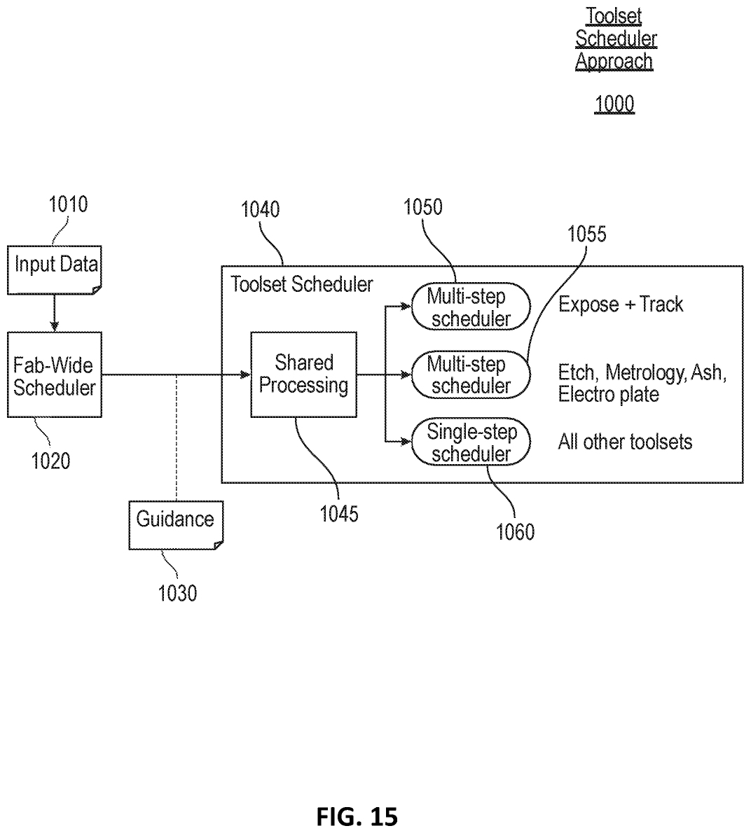

With reference to FIG. 15, an embodiment where a toolset scheduler approach 1000 is shown will now be described in more detail.

Input data 1010 is provided to the multi-machine/fab-wide scheduler 1020 from which a global/plant/fab-wide schedule is generated as described in relation to the embodiments above and elsewhere in this specification.

Optionally guidance data/input 1030 is provided along with the fab-wide schedule. The optional guidance data/input 1030 can include WIP targets; priorities; due dates; release data and other relevant data.

Shared processing 1045 is used to perform computation and the outputs provided to the multistep scheduler(s) 1050, 1055 and to the single step scheduler(s) 1060. The process used by the multistep scheduler(s) 1050, 1055 is described in relation to the embodiments above and elsewhere in this specification. The shared processing 1045 can include processing hardware resources such as local processor cores and/or virtual computing devices hosted remotely such as in a cloud environment.

In this embodiment, a solution strategy of the single step scheduler 1060 will be described. This solution strategy is effective when the toolset is not involved in constraints that couple many sequential steps.
Step 1 of the solution strategy is to generate an initial schedule which does not require significant computation. In one embodiment, this is generated using dispatch rules and/or discrete time simulation (which include dispatching rules) such as those which are typically used in fabrication plants to produce wafers.
Step 2 of the solution strategy is to filter the tasks (e.g. products/wafers/lots) based on a predefined time window. This time window includes tasks that are expected to be executed with high accuracy compared to future tasks that are subject to high uncertainty (as, the future one looks ahead, the higher the errors in transition/processing times and the higher the probabilities for machines to fail).
Step 3 of the solution strategy is to use computationally expensive optimisation-based models (for example including constraint programming and/or mixed integer linear programming modelling or other suitable models/approaches as mentioned elsewhere in this specification) that schedule only the short term tasks that have been filtered in Step 2.
Step 4, which can be optional in some embodiments, is to reconcile the two schedules from the unfiltered tasks remaining from the schedule produced in Step 1 and the optimised filtered tasks output from Step 3. The final schedule is then provided to be executed by the manufacturing plant/wafer fabrication facility.

This can result in an improved schedule maximising the objective set by the user (for example to reduce cycle time, increase throughput, optimise use of expensive secondary resources) and should result, in at least some embodiments, in an improvement in the cycle time of all of the tasks after performing all steps of the model/solution strategy presented above.

In some embodiments, the multi-machine/fab-wide scheduler can use any or any combination of the approaches/methods/techniques describer in relation to either or both of the multi-step scheduler and the toolset scheduler. Similarly, in some embodiments the multi-step scheduler can use any or any combination of the approaches/methods/techniques describer in relation to either or both of the multi-machine scheduler and the toolset scheduler. Also, in some embodiments the toolset scheduler(s) can use any or any combination of the approaches/methods/techniques describer in relation to either or both of the multi-step scheduler and the multi-machine scheduler.

The above-described embodiments and/or aspects can be hosted on a cloud computing infrastructure, or locally to a manufacturing/fabrication facility, or in a hybrid arrangement across remote and local computing systems. This can allow the more computationally expensive functions to be performed at a remote computer system and/or distributed computer system and/or cloud computing infrastructure while local computer systems can receive real-time data with high frequency and low latency that can then be used to update the generated schedule with adjustments based on changing local circumstances.

Any system feature as described herein may also be provided as a method feature, and vice versa. As used herein, means plus function features may be expressed alternatively in terms of their corresponding structure.

Any feature in one aspect may be applied to other aspects, in any appropriate combination. In particular, method aspects may be applied to system aspects, and vice versa. Furthermore, any, some and/or all features in one aspect can be applied to any, some and/or all features in any other aspect, in any appropriate combination.

It should also be appreciated that particular combinations of the various features described and defined in any aspects can be implemented and/or supplied and/or used independently.

1-40. (canceled)

41. A method of generating manufacturing scheduling data, comprising:
receiving input data, the input data comprising: at least one product to be manufactured; at least one sequence of steps associated with each of the at least one product to be manufactured; and at least one constraint associated with each of the at least one sequence of steps;
performing a plurality of different simulations of manufacturing the at least one product to be manufactured; wherein each of the plurality of different simulations uses different simulation parameters; and wherein each simulation determines a probability of breach of at least one of the at least one constraints;
determining a manufacturing schedule of the at least one product to be manufactured using the determined probability of breach of at least one of the at least one constraints;
determining a priority of each step in the at least one sequence of steps based on the determined manufacturing schedule;
generating manufacturing scheduling data, wherein the manufacturing scheduling data comprises one or more of the at least one sequence of steps associated with each of the at least one product to be manufactured and the determined priorities of the one or more of the at least one sequence of steps associated with each of the at least one product to be manufactured;
outputting the generated manufacturing scheduling data.

42. The method of claim 41, wherein determining a priority of each step based on the determined manufacturing schedule further comprises determining the priority of each step based on the determined probability of breach of at least one of the at least one constraints.

43. The method of claim 41, wherein the at least one product to be manufactured comprises any or any combination of: a semiconductor wafer product.

44. The method of claim 41, wherein each of the at least one sequence of steps associated with each of the at least one products to be manufactured comprises any or any combination of: steps to take in parallel; steps to take in sequence.

45. The method of claim 41, wherein the input data further comprises at least one buffer item to be released; wherein the at least one product to be manufactured requires one or more of the at least buffer items during its manufacture, optionally wherein determining a manufacturing schedule further comprises determining when to release one or more of the at least one buffer items to be released.

46. The method of claim 45, wherein determining a priority further comprises determining a priority of when to release one or more of the at least one buffer items to be released.

47. The method of claim 41, wherein the at least one constraint comprises any or any combination of: a time link constraint; a resource constraint; a product completion target associated with one or more of the at least one products to be manufactured.

48. The method of claim 41, wherein the input data further comprises a criticality value for at least one of the at least one constraints, wherein the criticality value optionally further comprises at least one priority value and/or wherein performing the plurality of simulations comprises preparing a ranking of the at least one product to be manufactured and/or each step in the at least one sequence of steps associated with each of the at least one product to be manufactured based on the one or more criticality values.

49. The method of claim 41, wherein the input data further comprises availability data of a plurality of manufacturing machines, wherein the at least one product to be manufactured is manufactured using the one or more of the manufacturing machines.

50. The method of claim 41, wherein performing the simulations comprises performing simulations of manufacturing only the at least one product to be manufactured within a predetermined time frame.

51. The method of claim 41, wherein determining the manufacturing schedule further comprises determining any or any combination of: an earliest and/or latest release time associated with one or more of the at least one product to be manufactured and/or one or more of the at least one sequence of steps associated with each of the at least one product to be manufactured.

52. The method of claim 41, wherein determining the manufacturing schedule is performed only for the at least one product to be manufactured where the determined probability of breach of at least one of the at least one constraints is below a predetermined threshold.

53. A method of generating scheduling data for manufacturing comprising:
receiving input data, the input data comprising a plurality of products to be manufactured and a plurality of tasks to be performed by each of a plurality of machines and wherein each of the plurality of tasks to be performed has a priority value associated therewith;
performing one or more simulations, each simulation determines a predicted outcome of at least some of the tasks to be performed, based on the availability of the plurality of machines and any pre-determined constraints, along with a probability of breaching any constraints;
determining a substantially optimal predicted outcome of the one or more simulations using pre-determined criteria;
generating scheduling data comprising an ordered set of tasks per machine based on the simulation used to determine the substantially optimal predicted outcome; and
instructing the plurality of machines to perform the plurality of tasks using the generated scheduling data to produce at least some of the plurality of products to be manufactured.

54. The method of claim 53 further comprising a step of pre-processing the plurality of tasks to be performed to select at least some of the plurality of tasks as a subset of tasks to be used by the one or more simulations to determine a predicted outcome of the subset of tasks to be performed.

55. The method of claim 53, wherein the input data further comprises any or any combination of: a state of the plurality of machines; an initial state of one or more resources; a state of a fabrication facility: one or more locations of any relevant products; a current task of one or more of the machines; an idle state of one or more of the machines; a maintenance state of one or more of the machines; a demand of one or more of the products; a priority of one or more products; specific due dates of one or more products.

56. The method of claim 53, wherein the priority value of each of the plurality of tasks indicates any or any combination of: an urgency value; an importance value; a relative urgency value; a relative importance value.

57. The method of claim 53, wherein performing one or more simulations comprises predicting one or more violations that would result in manufacturing defects and wherein determining the substantially optimal predicted outcome comprises substantially minimising predicted violations.

58. The method of claim 57, wherein the input data comprises a predetermining tolerance level of violations and wherein substantially minimising predicted violations comprises determining that the substantially optimal predicted outcome results in fewer violations than the predetermining tolerance level of violations.

59. The method of claim 53, further comprising a step of determining a level of robustness of the substantially optimal predicted outcome; and determining whether the level of robustness exceeds a predetermined tolerance level of robustness.

60. A method of generating scheduling data for manufacturing comprising:
receiving input data, the input data comprising a plurality of products to be manufactured and a plurality of tasks to be performed by each of a plurality of machines and wherein each of the plurality of tasks to be performed has a priority value associated therewith;
using a predictive model of the plurality of machines to determine a substantially optimal order of tasks per machine, based on the availability of the plurality of machines and any pre-determined constraints, along with a probability of breaching any constraints, is output; and
generating scheduling data comprising an ordered set of tasks per machine wherein scheduling data is operable to be used by the plurality of machines to manufacture at least some of the plurality of products to be manufactured.
